(19) United States
(12) Patent Application Publication
(10) Pub. No.: US 2025/0336643 A1
(43) Pub. Date: Oct. 30, 2025

(54) ELECTRON BEAM PROCESSING METHODS

(71) Applicant: Multibeam Corporation, Santa Clara, CA (US)

(72) Inventors: Andrew Ceballos, Mountain View, CA (US); Ted Prescop, San Jose, CA (US); Eli Vronsky, San Francisco, CA (US); Justin Fortner, San Jose, CA (US)

(73) Assignee: Multibeam Corporation, Santa Clara, CA (US)

(21) Appl. No.: 18/813,392

(22) Filed: Aug. 23, 2024

Related U.S. Application Data
(60) Provisional application No. 63/640,020, filed on Apr. 29, 2024.

(51) Int. Cl. H01J 37/317; H01J 37/147; H01J 37/20

(52) U.S. Cl. CPC H01J 37/3177; H01J 37/147; H01J 37/20; H01J 2237/1503; H01J 2237/20221; H01J 2237/31754; H01J 2237/31774

(57) ABSTRACT

A method for electron beam processing is described herein. A method includes disposing a substrate on a stage of a processing tool comprising a plurality of independently powered, independently controlled modular electron beam devices, concurrently directing a plurality of electron beams from the plurality of electron beam devices to the substrate to process different areas of the substrate concurrently, and, while directing the electron beams to the substrate, moving the substrate at a first constant velocity during a first scan pass and at a second constant velocity during a second scan pass, the first constant velocity being different from the second constant velocity.

### CROSS-REFERENCE TO RELATED APPLICATIONS

This patent application claims priority benefit of U.S. Provisional Patent Application Ser. No. 63/640,020 filed Apr. 29, 2024, which is entirely incorporated herein by reference.

### FIELD

Embodiments relate to methods for processing substrates using electron beams. In particular, this application is about methods for processing substrates using modular miniature electron beam devices that produce electrons.

### BACKGROUND

Electron beam technologies are used in many manufacturing settings, most notably in semiconductor manufacturing. While electron beam techniques for lithography can enable highly customized variations on a substrate such as a semiconductor wafer, processing an entire workpiece using electron beam lithography can be prohibitively time consuming. Methods, systems, and apparatus are needed for faster, more cost-effective electron beam processing.

### SUMMARY

Embodiments described herein provide a method comprising disposing a substrate on a stage of a processing tool comprising a plurality of independently powered, independently controlled modular electron beam devices; concurrently directing a plurality of electron beams from the plurality of electron beam devices to the substrate to process different areas of the substrate concurrently; and, while directing the electron beams to the substrate, moving the substrate at a first constant velocity during a first scan pass and at a second constant velocity during a second scan pass, the first constant velocity being different from the second constant velocity

Other embodiments described herein provide a method comprising disposing a substrate on a stage of a processing tool comprising a plurality of independently powered, independently controlled electron beam devices; selecting a power for each electron beam device based on a plan for writing features on the substrate; and concurrently directing a plurality of electron beams from the plurality of electron beam devices, at each respective selected power, to the substrate to process different areas of the substrate concurrently.

Other embodiments described herein provide a method comprising disposing a substrate on a stage of a processing tool comprising a plurality of independently powered, independently controlled electron beam devices; concurrently and continuously directing a plurality of electron beams from the plurality of electron beam devices to the substrate to process different areas of the substrate concurrently; and moving each beam of the plurality of electron beams at a first speed in a first area of the substrate and a second speed in a second area of the substrate, wherein the first speed is selected to deliver an exposure dose to the first area and the second speed is selected to deliver a non-exposure dose to the second area.

Other embodiments described herein provide a method comprising disposing a substrate on a stage of a processing tool comprising a plurality of independently powered, independently controlled electron beam devices; concurrently directing a plurality of electron beams from the plurality of electron beam devices to the substrate to process different areas of the substrate concurrently; and, while directing the electron beams to the substrate, moving the substrate at a constant velocity, wherein the processing of at least one of the areas of the substrate comprises moving the beam in an exposure area of the substrate at a first rate to deliver an exposure dose to the exposure area, and moving the beam in a non-exposure area of the substrate at a second rate to deliver a non-exposure dose to the non-exposure area.

Other embodiments described herein provide a method comprising directing a plurality of electron beams from a plurality of independently powered, independently controlled modular electron beam devices to concurrently process a plurality of areas of a substrate on a stage; and while concurrently processing the plurality of areas of the substrate on the stage, moving the stage at a first constant velocity during a first scan pass and at a second constant velocity during a second scan pass, the first constant velocity being different from the second constant velocity.

### BRIEF DESCRIPTION OF THE DRAWINGS

Some example embodiments are illustrated, by way of example and not limitation, in the accompanying figures. In the figures, like reference numbers indicate like features, and features might not be drawn to scale.

FIG. 1 is a schematic cross-sectional view of a processing tool according to one embodiment.

FIG. 2 is an isometric view of a substrate support used in embodiments of the processing tool of FIG. 1, according to one embodiment.

FIG. 3 is an isometric view of a substrate support used in embodiments of the processing tool of FIG. 1, according to another embodiment.

FIG. 4A is a plan view of an arrangement of an array of electron beam devices relative to a substrate, according to one embodiment, and FIG. 4B is an isometric view of FIG. 4A.

FIGS. 5A-5C are plan views of an arrangement of an array of electron beam devices relative to a substrate, according to one embodiment.

FIGS. 6A-6B are plan views of an arrangement of an array of electron beam devices relative to a substrate, and FIG. 6C is a schematic view of overlapping scan passes, according to one embodiment.

FIG. 7 is a plan view of a region of a substrate and corresponding fields of view of two adjacent features to be exposed.

FIGS. 8A and 8B are plan views of a region of a substrate and a corresponding field of view of a feature to be exposed.

### DETAILED DESCRIPTION

Methods for electron beam processing of substrates are described herein. The methods use a plurality of modular miniature electron beam devices in a processing tool to generate electron beams independently. The methods concurrently write patterns to a substrate using the plurality of electron beam devices. The methods use a plurality of independently controlled electron beam devices that can be operated at different power levels and/or write different patterns during concurrent processing of a substrate using the plurality of electron beam devices.

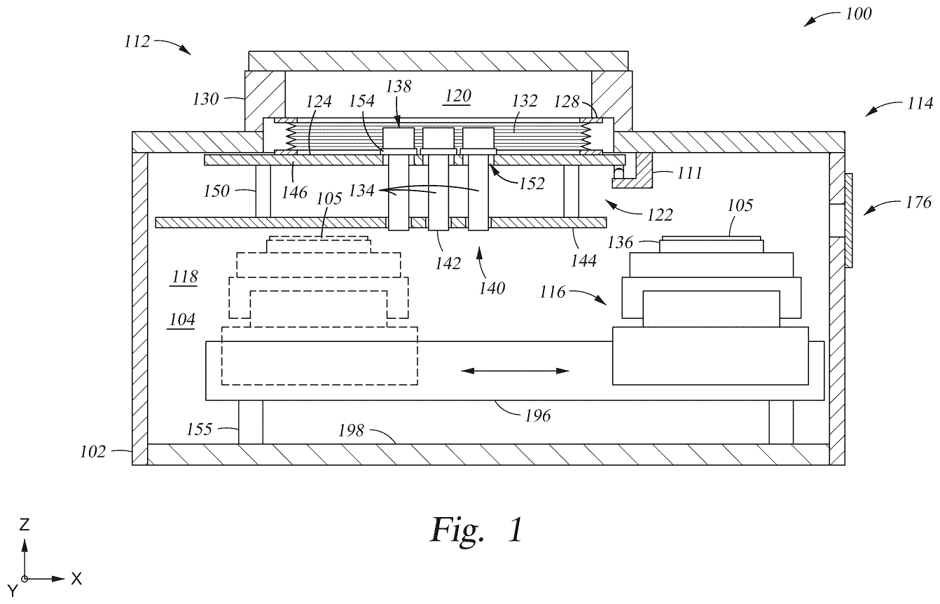

FIG. 1 is a schematic cross-sectional view of a processing tool 100 according to one embodiment. The processing tool 100 can be used in a processing system for mass production of processed substrates. The processing tool 100 has an enclosure 102 that encloses an interior 104. A plurality of pumps (not shown) operate to reduce a pressure within the enclosure 102 while processing a substrate 105. In one case, the pressure in the interior 104 is less than 10⁻⁷ Torr while processing a substrate. The processing tool 100 can thus be a vacuum tool.

The enclosure 102 is elongated in one dimension, denoted in FIG. 1 as the “x” dimension or direction. The elongated enclosure 102 has a processing section 112 and a loading section 114, which are typically displaced in the x-direction by a distance of more than the dimension of the substrate 105 to be processed using the processing tool 100. A movable substrate support 116 is capable of moving between the loading section 114 and the processing section 112 to enable substrates to be loaded onto the substrate support 116, and unloaded from the substrate support 116, in the loading section, and to be processed in the processing section 112.

The interior 104 of the enclosure 102 is divided into two volumes, a first volume 118, which contains the substrate support 116, and a second volume 120. The first volume 118 extends the length of the enclosure 102 from the processing section 112 to the loading section 114. The second volume 120 is located at the processing section 112 only. The first volume 118 is separated from the second volume 120 by a separation assembly 122 that provides a floor 124 of the second volume 120. A support 111 extends from an interior surface of the enclosure 102 to support the separation assembly 122. The support 111 is within the first volume 118 of the interior 104 because the second volume 120 is above the first volume 118. The separation assembly 122 is attached to the enclosure 102 at a wall 128 thereof to provide a barrier to fluid communication between the first volume 118 and the second volume 120. The separation assembly 122 allows the first volume 118 to be operated at a first volume pressure that can be different from a second volume pressure of the second volume 120. For example, the first volume pressure can be 10⁻⁷ Torr or more while the second volume pressure is 10⁻⁹ Torr or less. In such cases, the first volume 118 can be said to operate under high vacuum while the second volume 120 operates under ultra high vacuum. In other cases, the first volume pressure can be less than the second volume pressure. For example, the second volume pressure can be near atmospheric pressure while the first volume pressure is vacuum such as 100 Torr.

The separation assembly 122 provides support for a plurality of modular miniature electron beam devices 134 that emit electrons into the first volume 118 for processing the substrate 105 disposed on a stage 136 of the substrate support 116, when the substrate support 116 is positioned in the processing section 112. The electron beam devices 134 are disposed through the separation assembly 122, with an emitter portion 138 of each electron beam device 134 located in the second volume 120 and a direction portion 140 of each electron beam device 134 located in the first volume 118. Here, an exit end 142 of the electron beam devices 134 is exposed within the first volume 118 so that electrons emitted by an electron emitter within the emitter portion 138 and directed using the direction portion 140 exit the exit end 142 of the electron beam devices 134 into the first volume 118 and travel toward the stage 136 to interact with the substrate 105 thereon. Here, the electron beam devices 134 are configured to emit electrons from the exit end 142 in a beam configuration, and focus elements of the direction portion 140 of each electron beam device 134 are operable to configure the electrons in an electron beam that may be focused, defocused, or collimated to any suitable extent depending on processing needs of the substrates to be processed. The direction portion 140 is operable to configure a shape of the beam, e.g., a shape of an irradiated region of the substrate 105, to be round, square, oval or any other suitable shape, and to control beam energy, e.g., a current density, within the beam profile. The electron beam devices 134 are elongated, at least in the direction portions 140, to provide propagation length usable to configure the electrons into a beam configuration. Here, the separation assembly 122 is oriented in a substantially horizontal orientation, and the electron beam devices 134 are oriented to extend in a substantially vertical direction, which may be substantially perpendicular to a plane defined by the separation assembly 122.

The separation assembly 122 of FIG. 1 has a first support member 144 and a second support member 146. The first and second support members 144 and 146 are oriented in parallel, one to the other, and are spaced apart a selected distance. As noted above, in this case the processing tool 100, and the separation assembly 122, are oriented horizontally, such that the second volume 120 is located vertically above the first volume 118, but the processing tool 100 can generally take any suitable orientation.

Each of the first and second support members 144 and 146 has a plurality of openings 152 to accommodate the electron beam devices 134. The first and second support members 144 and 146 are configured such that the openings 152 of each member are in registration with the openings of the other plate. Thus, each opening 152 of the first support member 144 has a corresponding opening in the second support member 146, and the respectively corresponding openings 152 are aligned such that an electron beam device 134 can pass through corresponding openings in the first and second support members 144 and 146. As explained above, the spacing of the first and second support members 144 and 146 is selected such that each electron beam device 134 can make electrical connection with contacts adjacent to an opening 152 of the first support member 144 and with contacts adjacent to a corresponding opening 152 of the second support member 146 when the electron beam device 134 is inserted through the openings 152 and seated into place.

The processing tool 100 has electrical couplings disposed within an interior space of the separation assembly 122. The electrical couplings deliver power to, and transmit electrical signals to and from, all the electron beam devices 134. The electrical couplings may be members of the separation assembly 122. One of the electrical couplings may include circuitry, which may be digital circuitry, analog circuitry, or a combination thereof, to deliver power, which may be high voltage, low voltage, or intermediate voltage power, or any combination thereof, to power components of each electron beam device 134, such as the electron emitter housed within the emitter portion 138 and analog control elements of the direction portion 140. Thus, one of the electrical couplings may be, or may include, a power circuit member. Another of the electrical couplings may include digital circuitry for sending and receiving signals to each electron beam device 134. Thus, one of the electrical couplings may be, or may include, a signal circuit member that handles all control of the electron beam devices 134.

As described above, the direction portion 140 of each electron beam device 134 can have analog controls to control propagation of electrons through the direction portion 140 and out of the electron beam device 134 through the exit end 142 thereof. Each electron beam device 134 can include a D-A converter to convert digital control signals to analog control signals and apply the analog control signals to the analog controls of the direction portion 140. A method of processing the substrate 105 may therefore include an operation of independently providing respective digital signals to respective ones of a plurality of electron beam devices 134, e.g., to independently control each electron beam device 134 while writing to the substrate 105 with the plurality of electron beam devices 134 concurrently.

The electron beam devices 134 typically also include sensors (not shown). The sensors generate analog signals representing a condition of the electron beam device 134 or an environment thereof. These signals can be transmitted as analog signals or the signals can be converted to digital signals using an A-D converter. In one embodiment, a method of processing the substrate 105 may therefore include an operation, e.g., a feedback operation, of independently controlling each electron beam device 134 using information from corresponding sensors such as a backscatter detector positioned at each exit end while writing to the substrate 105.

It should be noted that, whereas the processing tool 100 contains multiple modular electron beam devices 134, D-A and A-D conversion can be implemented differently for the different electron beam devices 134. That is, one or more of the electron beam devices 134 can have a D-A converter and one or more of the electron beam devices 134 can have an A-D converter. In one embodiment, a method of processing the substrate 105 includes performing independent A-D conversion on each electron beam device 134, such as A-D conversion of sensor signals such as a backscatter signal.

The direction portion 140 of each electron beam device 134 has a plurality of analog controls that can be manipulated to control shape, focus, and direction of electrons emitted from the exit end 142 of the electron beam device 134, independently of the other electron beam devices 134 in the processing tool 100. In many cases, the analog controls are used to form the electrons into a beam configuration having a desired dimension or focus and landing on the substrate 105 at a target location. The controls are manipulated to articulate the electron beam to different locations on the substrate 105 to “write” a pattern on the substrate 105 using the beam of electrons. A method of processing the substrate 105 includes such writing to expose a layer on the substrate 105 that is sensitive to electron exposure. The layer may respond to electron exposure in a dose-dependent manner in which a relatively lower dose of electrons does not significantly alter the layer whereas a relatively higher dose of electrons does alter the layer, e.g., to create a pattern in the layer. The dose of electrons can be controlled by controlling a residence time of the electron beam on a location of the layer and/or controlling a flux density of electrons in the electron beam.

Use of multiple modular miniature electron beam devices 134, as in the processing tool 100, enables much faster processing of substrates by allowing concurrent processing of sections of the substrate 105 by independently operating the electron beam devices 134. Where digital control signals are involved, each electron beam device 134 is controlled using digital signals using a digital-analog converter that translates digital signals into analog signals that are applied to the analog controls. Such configurations allow processing methods in which different sections of a substrate 105 are concurrently processed using, e.g., electron beams writing different patterns, potentially with different beam size, shape, intensity, and dose. One location of a substrate 105 can even be treated to a first writing process using a first electron beam device 134, and the same location can then be treated to second writing process using a second electron beam device 134 of the same processing tool 100. The two writing processes can treat the location using different doses, intensities, and/or illumination areas to achieve any desired treatment effect on the substrate 105.

Use of an electrical coupling member to couple power to each electron beam device 134, as shown in FIG. 1 and described herein, enables power delivery to each electron beam device 134 independent of every other electron beam device 134. Power can be separately switched to individual circuits for delivery to specific electron beam devices 134. In some cases, each electron beam device 134 can have a separate, dedicated power supply. Thus, for a processing tool like the processing tool 100 that uses multiple, e.g., nine, electron beam devices 134, multiple, e.g., nine, power supplies can be connected, one power supply to one electron beam device 134, to power each electron beam device 134 independently. The same can be done for processing tools using any number of electron beam devices 134 in the configuration described herein.

One embodiment of a method of processing the substrate 105 includes disposing the substrate 105 on the stage 136 of the processing tool 100 having a plurality of the electron beam devices 134, which are independently powered and independently controlled, selecting a power (e.g., beam energy, beam current, beam spot size, and/or beam current density) for each electron beam device 134 based on a feature of the substrate 105, or based on a plan or recipe for writing patterns on the substrate 105, and concurrently directing a plurality of electron beams from the plurality of electron beam devices 134, at each respective selected power, to the substrate 105 to process (or write to, or expose) different areas of the substrate 105 concurrently using the respective powers. In some examples, beam energies of the electron beams from the electron beam devices 134 are controlled to be about 2-7 keV, 7-10 keV, or 10-15 keV. Other beam energies can also be used, and the electron beam devices 134 can be operated concurrently at different power levels selected for each individual electron beam device based on a feature to be formed by that electron beam device or based on a plan or recipe the electron beam device is to follow for writing patterns or features on the substrate.

In one example, each selected power is based on a feature of the substrate 105 within an area of the substrate 105 that is to be processed, according to the plan or recipe, using the respective electron beam device 134. The feature can be a material forming a layer of the substrate, e.g., a resist layer or the like, and/or a thickness of a layer on the substrate. In another example, each selected power, or one or more selected powers, can be selected based on a planned exposure rate using the electron beam device. For example, where a first electron beam device is to be used to deliver a first planned exposure rate, and the second electron beam device is to be used to deliver a second planned exposure rate different from the first planned exposure rate, a first power can be selected for the first electron beam device, and a second power, different from the first power, can be selected for the second electron beam device. Independent control of power to each electron beam device enables concurrently operating the first electron beam device at the first power and operating the second electron beam device at the second power.

Selecting the power for each electron beam device 134 can include selecting power information or a power specification from a memory, e.g., from a data table or database stored in the memory. In one case, the power information or specification can be stored in the memory as part of the plan or recipe for writing patterns on the substrate 105. In another case, selecting the power for each electron beam device 134 can include instructing a digital control system to automatically select the powers, whether from a pre-configured plan or recipe, or on the fly.

In one embodiment, controlling the power delivery to each electron beam device 134 independently of every other electron beam device 134 in the processing tool 100 is used to provide independent calibration for each electron beam device 134. Calibration settings can be saved in a memory on the electron beam device 134 or in a memory matched to the electron beam device 134, e.g., by using a unique identifier for each electron beam device, to thus allow each electron beam device 134 to be calibrated to a same standard despite possible performance differences among electron beam devices 134, e.g., due to different characteristics of the emitter portions 138, different ages of the emitters, or the like.

In operation, the electron beam devices 134 emit electrons at the emitter portion 138 and direct the electrons in the direction portion 140 into the first volume 118 toward the stage 136 of the substrate support 116, on which the substrate 105 is disposed for processing. The electrical couplings provide independent power and control to each electron beam device 134 so that different portions of the substrate 105 can be processed in different ways concurrently and independently. It should be noted that, where suitable in some cases, multiple electron beam devices of a processing tool such as the processing tool 100 can be independently controlled to the same nominal power level. The capability to independently control the electron beam devices 134 enables processing the substrate 105 at a high rate by independently and concurrently processing different portions of the substrate 105.

As described above, the substrate support 116 is movable between the processing section 112 and the loading section 114. The substrate 105 is disposed on the stage 136 of the substrate support 116 in the loading section 114, and then moved to the processing section 112 by the substrate support 116. The processing tool 100 includes a substrate port 176 coupled to an opening of the enclosure 102 to allow loading and unloading of substrates 105. A substrate handler (not shown) is generally configured to transport the substrate 105 through the substrate port 176 and deposit the substrate onto the stage 136, and to retrieve the substrate 105 from the stage 136 and withdraw the substrate 105 through the substrate port 176. The substrate port 176 may be any suitable port, such as a door, gate, or slit. The stage 136 generally includes a chucking provision to hold the substrate 105 on the stage 136. The chucking provision can be an electrostatic chuck or vacuum chuck, depending on processing conditions within the processing tool 100.

The substrate support 116 moves along an x-direction movement component 196, which may be a rail system, disposed in a lower portion of the interior 104 of the enclosure 102, in this case on the floor 198 of the enclosure 102.

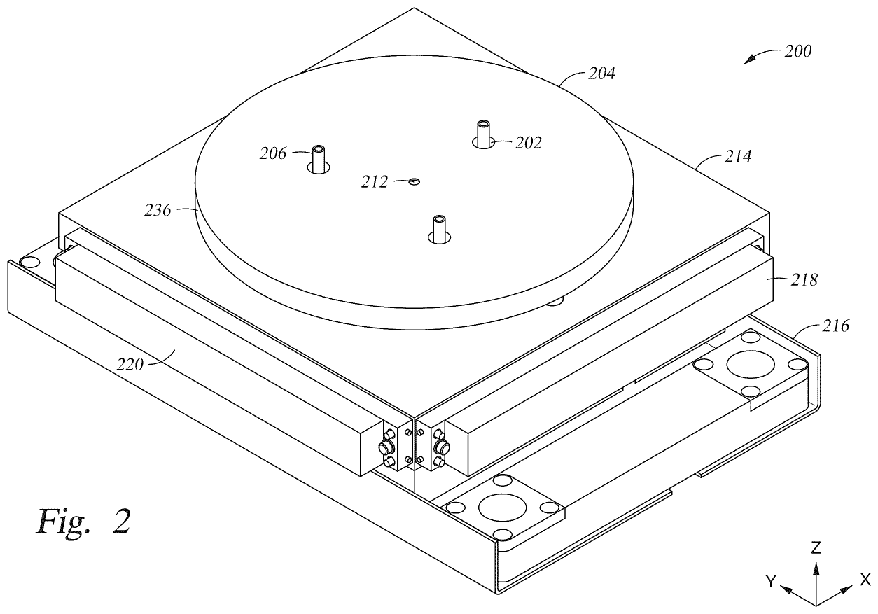

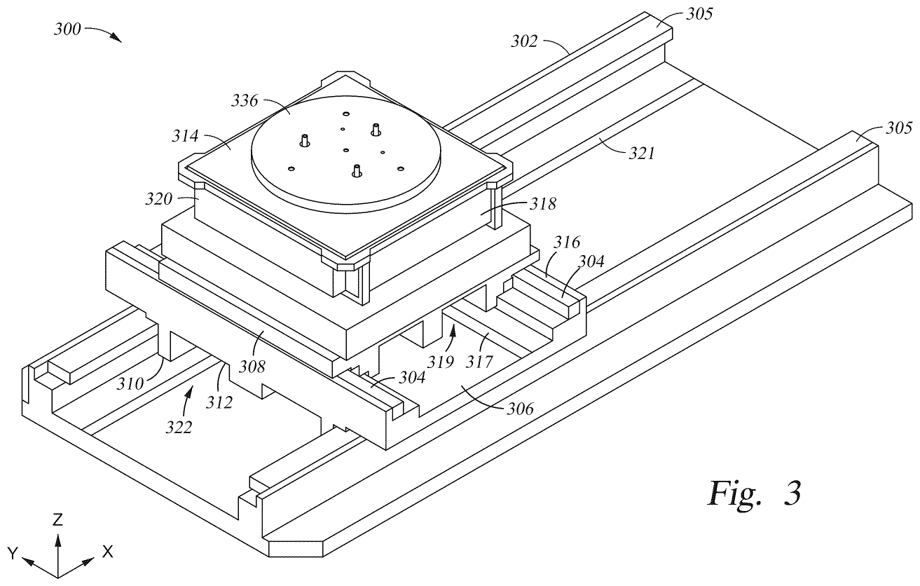

FIG. 2 is a perspective view of a substrate support 200 according to one embodiment. The substrate support 200 can be used in the processing tool 100 as the substrate support 116 in FIG. 1 or can be used as part of a substrate support described below in connection with FIG. 3. The substrate support 200 has a stage 236, on which a substrate is to be disposed, and which has a plurality of lift openings 202 formed in a support surface 204 thereof. In this case there are three lift openings 202 but any suitable number of lift openings can be used, through which lift members 206 deploy to raise and lower the substrate for handling. The substrate support 200 generally has an interior volume (not shown) in which a lift mechanism can be disposed to operate to extend the lift members 206 through the lift openings 202 and to retract the lift members 206 into the stage 236, below the support surface 204. The stage 236 can incorporate an electrostatic chuck. Other types of substrate support or support stages can be used. For example, wafer clamp supports can also be used. The stage 236 can also include one or more temperature sensors (not shown), which may be located against an under side surface of the stage 236.

The stage 236 may have an electrically conductive recess 212 in the support surface 204 at a central location. The electrically conductive recess 212 can be a metal cup structure. The electrically conductive recess 212 can be used to measure flow of electric current from an electron beam of one or more of the electron beam devices 134 (FIG. 1) as the stage 236 is sequentially positioned under the one or more electron beam devices 134. The substrate support 200 is operated to position the stage 236 such that the electrically conductive recess 212 is in the path of electrons travelling from one of the electron beam devices 134 (FIG. 1) to the stage 236. The electrically conductive recess 212 can be electrically connected to sensors to measure electrical properties of the electrically conductive recess 212, from which flow of electrons into the electrically conductive recess 212 can be inferred. A method of processing a substrate may include an operation, e.g., a preliminary operation performed before mounting the substrate to the stage 236, of calibrating one or more of a plurality of electron beam devices 134 using electric current measurements from the electrically conductive recess 212 of corresponding electron beams.

The stage 236 is attached to a base 214. The base 214 is disposed on a movement member 216. The movement member 216 provides linear movement, e.g., in an x-direction or a y-direction in FIG. 1, for the stage 236 to position and move a substrate 105 for processing, or to move the electrically conductive recess 212 for beam current measurement. A linear actuator (not shown) is coupled to the movement member 216. The linear actuator moves a component of the movement member 216 that is attached to the base 214. The processing tool 100 may use an interferometry system for precision alignment and targeting of electrons to the substrate 105. Here, a first mirror 218 is attached to a first side of the base 214 and a second mirror 220 is attached to a second side of the base 214 orthogonal to the first side. The two mirrors 218, 220 can provide reflective measurement surfaces on the base 214 for measuring the location of the stage 236 to sub-micron precision. The substrate support 200 can include a rotational actuator (not shown) coupled to the base 214 to rotate the base 214 and the stage 236 as needed to orient a substrate disposed thereon. The rotational actuator can be located inside the substrate support 200. Coupling a rotational actuator to the base 214 can allow the adjustment of the rotational orientation of the substrate about the z-axis.

FIG. 3 is an isometric view of a substrate support 300 according to another embodiment. The substrate support 300 can be used in the processing tool 100 as the substrate support 116 of FIG. 1 The substrate support 300 has a stage 336, similar to the stage 236 of the substrate support 200 of FIG. 2. Whereas the first and second mirrors 218 and 220 of the substrate support 200 are attached using bolts, in this case brackets secure first and second mirrors 318 and 320. The brackets securing the second mirror 320 are omitted from this view for illustration purposes.

Here, a first movement member 316 (corresponding to the movement member 216 of FIG. 2) is coupled to a second movement member 302. The first movement member 316 has two rails 304 along a first side 306 thereof, on which a carriage member 308 of the base 314 is movably disposed to ride linearly along the rails 304. The first movement member 316 has a coupling structure 310 on a second side 312 thereof, opposite from the first side 306, for coupling with the second movement member 302 to ride linearly along the second movement member 302. The second movement member 302 has two rails 305 that couple with the coupling structure 310 of the first movement member 316 to support linear motion of the first movement member 316. Thus, the first movement member 316 moves along the second movement member 302 in a first linear direction while the stage 336 moves along the first movement member 316 in a second linear direction perpendicular to the first linear direction.

The first movement member 316 may have a metric member 317 that can be used to measure position of the stage 336 with respect to the first movement member 316. The metric member 317, in this case, is attached to the first side 306 of the first movement member 316, on a surface facing the carriage member 308 of the base 314. The carriage member 308 of the base 314 has a recess 319 that faces the first side 306 of the first movement member 316. The metric member 317 extends along the first side 306 of the first movement member 316 facing the recess 319 of the carriage member 308. A sensor (not shown) can be attached to the carriage member 308 within the recess 319 to sense markings (not shown) on the metric member 317 for determining position and movement speed of the stage 336 with respect to the first movement member 316. The sensor and the metric member 317 thus constitute a linear encoder coupled between the stage 336 and the first movement member 316 for sensing position and movement speed of the stage 336. Note that this configuration of a linear encoder is only one example, and that a linear encoder can be incorporated into any suitable surfaces of the carriage member 308 and the first movement member 316.

The second movement member 302 also has a linear encoder. In a configuration similar to that of the first movement member 316, a metric member 321 is coupled to a side of the second movement member 302 that faces the coupling structure 310 of the first movement member 316 and extends into a recess 322 of the coupling structure 310. A sensor (not shown) can be attached to the coupling structure 310 facing the metric member 321 to sense position and velocity of the first movement member 316 with respect to the second movement member 302.

In on example of a method of positioning the stage 336 using interferometry, a light source (not shown) is used to provide a beam of light having sufficient coherence for precise interferometric measurements. The beam of light may be a laser beam. A first beam splitter provides a reference beam and a probe beam. The probe beam is split by a second beam splitter into a two beams, which are directed to the first mirror 318 and the second mirror 320, and used to measure the position of the stage 336 in two orthogonal dimensions by comparing reflected beams to the reference beam, to compute distance. The beam directed to the second mirror 320 may itself be further split into two beams that are directed at different locations of the second mirror 320 to measure differential distance for ascertaining rotational orientation of the stage 336.

In a substrate processing operation, the substrate 105 can be processed in the processing tool 100 using the substrate support 300. The linear encoders and interferometry can be used to control the location of application of electrons from the electron beam devices 134 to precise locations on the substrate 105 for precise durations. In one embodiment, a method includes operating the substrate support 300 to scan the substrate 105 at a constant velocity during processing. Sensors of the linear encoders output signals representing position of the stage 336, and a controller uses the signals to control linear actuators to maintain a very constant scan speed or scan velocity of the substrate 105 during processing. As the substrate 105 is scanned, the analog controls of the electron beam devices 134 are operated, using control signals, which may be digital control signals, provided by the controller, to perform a writing process on the substrate 105 by directing an electron beam having controlled beam diameter, shape, intensity, and/or duration to target locations of the substrate 105. The interferometry system continuously registers position of the stage 336 and detects any deviation from linear, constant velocity motion of the stage 336. The controller uses signals from the interferometry system to control the electron beam devices 134, by routing signals to the analog controls of the electron beam devices 134, modifying the writing process to compensate for deviation of stage movement from constant linear velocity.

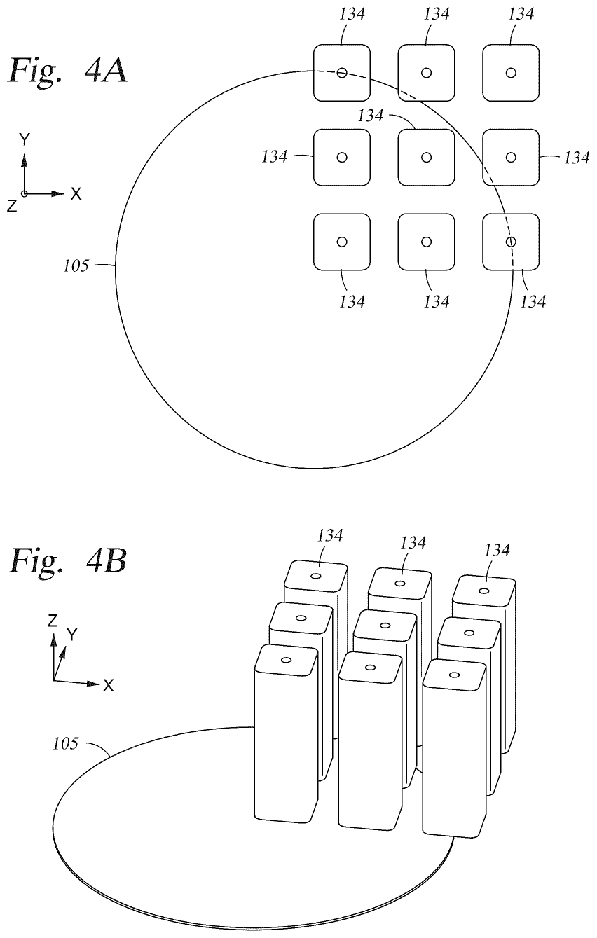

FIG. 4A is a plan view of an arrangement of an array of electron beam devices 134 relative to a substrate 105, according to one embodiment, and FIG. 4B is an isometric view of FIG. 4A. Each electron beam device 134 in the array is independently powered and independently controlled, relative to the other electron beam devices 134 in the array.

In FIGS. 4A and 4B, the array of electron beam devices 134 includes nine electron beam devices 134 arranged in three rows and three columns, byway of example. In other implementations, the array may include more or fewer electron beam devices 134, and may include more or fewer rows and/or columns. For example, a small array of the electron beam devices 134 may include only two electron beam devices 134, each of which is independently powered and independently controlled. Such an array may be a single row in the x-axis direction and two columns in the y-axis direction.

The rows and columns of the array of electron beam devices 134 may be equally spaced. In one embodiment, the electron beam devices 134 of the array are mounted to the separation assembly 122 of the processing tool 100 of FIG. 1, such that the exit end 142 of each of the electron beam devices 134 is exposed within the first volume 118 of the enclosure 102, and electrons emitted within each emitter portion 138 are directed, using the corresponding direction portions 140 of the electron beam devices 134, into the first volume 118 and travel toward the stage 136 to interact with the substrate 105 thereon.

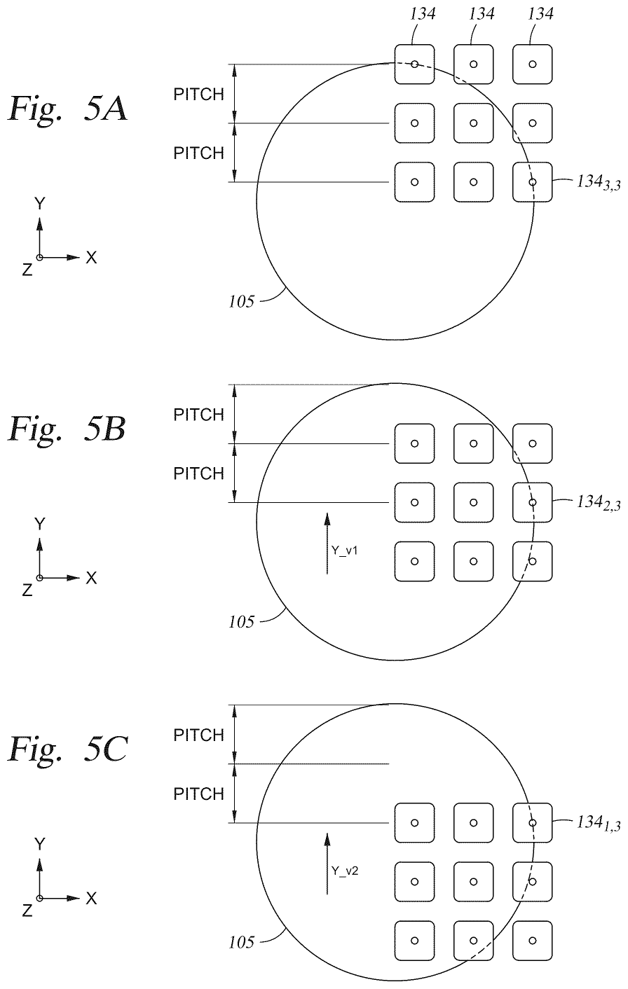

FIGS. 5A-C are plan views of an arrangement of an array of nine electron beam devices 134 relative to a substrate 105, according to one embodiment. As noted above, in a processing tool such as the tool 100, the electron beam devices 134 of the array are mounted to the separation assembly 122. In FIG. 1, rows extend in the x-direction and columns extend in the y-direction. The processing tool 100 including the array of electron beam devices 134 can process the entire surface of the substrate 105 by moving the stage 136 in x- and y-directions. The processing tool 100 moves the stage 136 in directions parallel to the x- and y-axes as one or more electron beam devices 134 of the array write to the surface of the substrate 105. The processing tool 100 moves the stage in directions parallel to the x- and y-axes so that all regions of the surface of the substrate 105 are movable under at least one of the electron beam devices 134.

In one embodiment, the processing tool 100 moves the stage 136 in the y-direction by at least one pitch of the electron beam devices 134 in the y-direction during a writing process. The processing tool 100 may move the stage 136 in the y-direction by two or more pitches of the electron beam devices 134. The pitch in the y-direction may be a center-to-center dimension of adjacent rows of the electron beam devices 134 (a row pitch) or a center-to-center dimension of electron beams or fields of view of the electron beam devices 134 in the y-direction. The processing tool 100 also moves the stage 136 in the x-direction, e.g., by at least one pitch in the x-direction. A column pitch of the electron beam devices 134 in the x-direction may be the same as or different from the row pitch in the y-direction.

In FIG. 5B, the stage 136 has moved the substrate 105 in the y-direction by one pitch, relative to FIG. 5A. Thus, whereas an electron beam device 134_{3,3} (the electron beam device 134 in the third row and third column of the array) is located at a periphery of the substrate 105 in FIG. 5A, an electron beam device 134_{2,3} (in the second row and third column of the array) is located at the periphery of the substrate 105 in FIG. 5B. In FIG. 5C, the stage 136 has moved the substrate 105 in the y-direction by one pitch, relative to FIG. 5B. Thus, an electron beam device 134_{1,3} (in the first row and third column of the array) is located at the periphery of the substrate 105 in FIG. 5C.

As described above, during a writing process, the processing tool 100 is controlled to move the stage 136 parallel to the y-axis to scan the substrate 105 at a constant velocity during processing, i.e., while electrons from the electron beam devices 134 are directed onto the substrate 105. Moving the substrate at a constant velocity from a first position to a second position, while directing electrons onto the substrate, is a scan pass. The first position may be a start position. Likewise, the second position may be a stop position. A scan pass corresponds to a region that is processable by a single electron beam device 134 of a processing tool 100 as the processing tool 100 moves a stage 136 in a single direction. A scan pass corresponds to a writing process and is distinguished from merely moving (or passing) the stage 136 (or the stage 136 and substrate 105) without any writing being performed. A scan pass can include exposing or writing to some regions of the substrate 105 but not others. For example, a scan pass can include writing patterns to the substrate 105, where such patterns are interspersed with unpatterned or unexposed regions of the substrate 105. For a case in which the processing tool 100 includes only a single row of electron beam devices 134, a single scan pass may substantially encompass a full diameter of the substrate 105 or more. For a case in which the processing tool 100 includes multiple rows or columns of electron beam devices 134, a scan pass may correspond to one pitch in the y-direction, or more than one pitch in the y-direction. A scan pass may include movement of the stage 136 and the substrate 105 in the x-direction. Where two scan passes have different locations in the x-direction, the scan passes can overlap, abut, or be spaced apart. That is, a first scan pass can have a first y-axis extent (y-axis distance exposed) and a first x-axis location, and a second scan pass can have the first y-axis extent and a second x-axis location different from the first x-axis location, where the first and second x-axis locations are displaced by a distance that is less than one pitch in the x-direction, substantially equal to one pitch in the x-direction, or more than one pitch in the x-direction. It should be noted that scan passes can have different extent in the y-direction. Thus, a first scan pass can have a first y-axis extent and a second scan pass can have a second y-axis extent different from the first y-axis extent.

In one embodiment, the processing tool 100 moves the stage 136 and the substrate 105 for a plurality of sequential scan passes that include a first scan pass at a first constant velocity and a second scan pass at a second constant velocity. The first constant velocity and the second constant velocity are non-zero. The second constant velocity is different from, i.e., greater than or less than, the first constant velocity. During the first and second scan passes, two or more electron beam devices 134 are operated to concurrently process, i.e., write to, different areas of the substrate 105 independently. Thus, in one embodiment, a method of processing the substrate 105 includes disposing the substrate 105 on the stage 136 of the processing tool 100 (which includes a plurality of independently powered, independently controlled modular electron beam devices 134), directing a plurality of electron beams from the plurality of electron beam devices 134 to the substrate 105 to process, i.e., write to, different areas of the substrate 105 concurrently, and, while directing the electron beams to the substrate 105, moving the substrate 105 at a first constant velocity, e.g., in the y-direction, during a first scan pass and at a second constant velocity, e.g., also in the y-direction, during a second scan pass, the first constant velocity being different from the second constant velocity.

By way of example, in FIG. 5B, the stage 136 has moved the substrate 105 in the y-direction by one pitch relative to FIG. 5A, and thus, FIG. 5B represents a first scan pass for at least one of the electron beam devices 134, relative to FIG. 5A. During the first scan pass, the stage 136 moves the substrate 105 in the y-direction at a first constant velocity Y_v1. In FIG. 5C, the stage 136 has moved the substrate 105 in the y-direction by one pitch relative to FIG. 5B, and thus, FIG. 5C represents a second scan pass for at least one of the electron beam devices 134, relative to FIG. 5B. During the second scan pass, the stage 136 moves the substrate 105 in the y-direction at a second constant velocity Y_v2 that may be the same as the first constant velocity Y_v1 or different from the first constant velocity Y_v1.

In one embodiment, a method of processing the substrate 105 includes moving the stage 136 and the substrate 105 at the first constant velocity (e.g., Y_v1) during the first scan pass and at the second constant velocity (e.g., Y_v2) during the second scan pass, with the first constant velocity (e.g., Y_v1) being determined based on a first density of exposure of the substrate 105 during the first scan pass, and the second constant velocity (e.g., Y_v2) being determined based on a second density of exposure during the second scan pass, the first density of exposure being different from the second density of exposure. The first constant velocity (e.g., Y_v1) may be based on a first maximum density of exposure of a first area of the substrate 105 during the first scan pass and the second constant velocity (e.g., Y_v2) may be based on a second maximum density of exposure of a second area of the substrate 105 during the second scan pass. In one example, the density of exposure refers to an electron flux density of electrons directed onto the substrate 105. In another example, the density of exposure refers to a density of patterns to be written to the substrate 105. In another example, the density of exposure refers to an area ratio of exposed to unexposed areas of the substrate 105 within a scan pass region of an electron beam device 134.

In one embodiment of the method, if a first region of the substrate 105 is to be exposed with a relatively lower density of exposure and a second region of the substrate 105 is to be exposed with a relatively higher density of exposure, then the processing tool 100 moves the stage 136 (and hence the substrate 105) at a relatively higher constant velocity during processing of the first region of the substrate 105 and at a relatively lower constant velocity during processing of the second region of the substrate 105.

Because each electron beam device 134 is independently controlled and can form different, independent patterns during concurrent processing of the substrate 105, the method, in which the substrate 105 is moved at a first constant velocity during a first scan pass and at a second constant velocity during a second scan pass, allows for optimizing a plan or recipe for patterning the substrate 105 whereby a planned pattern-forming operation of each electron beam device 134 in the array of processing tool 100 is compared to planned pattern-forming operations of the other electron beam devices 134 in the array or processing tool 100, and the comparisons are used to optimize, e.g., maximize, velocity of the stage 136 among scan passes of the plan or recipe. The method thus improves throughput relative to a method that uses a same constant velocity for all scan passes or all regions of the substrate 105.

In the example illustrated in FIGS. 5A-C, the first and second scan passes are both in a same direction, i.e., the substrate 105 is moving upward in the y-direction in FIGS. 5A-C. However, the substrate 105 may move in opposite directions in the y-direction in respective scan passes. Also, the substrate 105 may move in the x-direction during or between scan passes. For example, during a first scan pass the substrate may move is the positive y-direction from a start position to a stop position, move by one electron beam device pitch in the x-direction, and then during a second scan pass move in the negative y-direction from a start position to a stop position. Thus, scan passes can be taken in boustrophedonic fashion to process the substrate.

During each scan pass, the stage 136 moves so that the substrate 105 traverses the field of view (FOV) of an electron beam device 134 at a constant linear velocity, e.g., in a direction parallel to the y-axis as shown in FIGS. 5A-C. Also during each scan pass, electrons from each electron beam device 134 are independently directed, using the corresponding direction portions 140 of the electron beam devices 134, to specific locations of the substrate 105 within the fields of view (FOVs) of the corresponding electron beam devices 134. In one embodiment, the FOV of the electron beam device 134 is controlled to be a rectangular or square region, e.g., a square region of about 25 μm, 30 μm, or 50 μm on a side. In another embodiment, the FOV is controlled to be an elliptical or circular region, e.g., a circular region having a diameter of about 25 μm, 30 μm, or 50 μm. As the substrate 105 moves parallel to the y-axis, the electron beams may be scanned within the FOV in a direction that is orthogonal or substantially orthogonal to the direction of motion of the stage 136 and the substrate 105, i.e., the electron beams may be scanned laterally across the FOV in the x-axis direction. The electron beams may also be scanned vertically in the FOV in the y-axis direction, or scanned in directions that have both x- and y-axis components, e.g., diagonally, in a curve, back and forth, or the like.

The direction portions 140 of the electron beam devices 134 direct the electrons according to a plan or recipe. The plan or recipe may include concurrently forming different, independent patterns on the substrate 105 using each electron beam device 134. Thus, for example, two adjacent electron beam devices 134 may concurrently write two different patterns to the corresponding portions of the substrate 105 that pass through the FOVs of the two adjacent electron beam devices 134. Likewise, for the example array having nine electron beam devices 134, nine different patterns may be written to the substrate 105 concurrently. Thus, a writing method according to one embodiment includes writing to or processing different sections of a substrate 105 concurrently, using electron beams each writing different patterns, potentially with different beam size, shape, intensity, and dose.

Each scan pass may have a y-direction extent that is on the order of one row pitch in the y-direction, or that is at least a center-to-center distance of electron beams from adjacent electron beam devices 134. Each scan pass may have an x-direction extent that is on the order of one FOV in the x-direction. Thus, each scan pass has a substantially longer dimension along a fast-motion axis (the y-axis in FIGS. 5A-C) than along the orthogonal axis. The dimensions of the scan pass can be determined as stage movement along the fast-motion axis in one direction×width of the FOV in a second, orthogonal direction.

By way of example, for a case in which the processing tool 100 has a first electron beam device 134 and a second electron beam device 134 adjacent thereto in the y-axis direction (i.e., the first electron beam device 134 and the second electron beam device 134 are respectively in adjacent rows in an array) and the first and second electron beam devices 134 are arranged at a pitch of 75 mm, a scan pass is at least 75 mm in the y-axis direction, i.e., the stage 136 moves the substrate 105 by at least 75 mm in the y-axis direction. In this example, for a case in which the FOV of the electron beam device 134 is 250 μm in diameter, then one scan pass is at least 75 mm long and 250 μm wide. For a case in which the FOV of the electron beam device 134 is 25 μm in diameter, then one scan pass is at least 75 mm long and 25 μm wide.

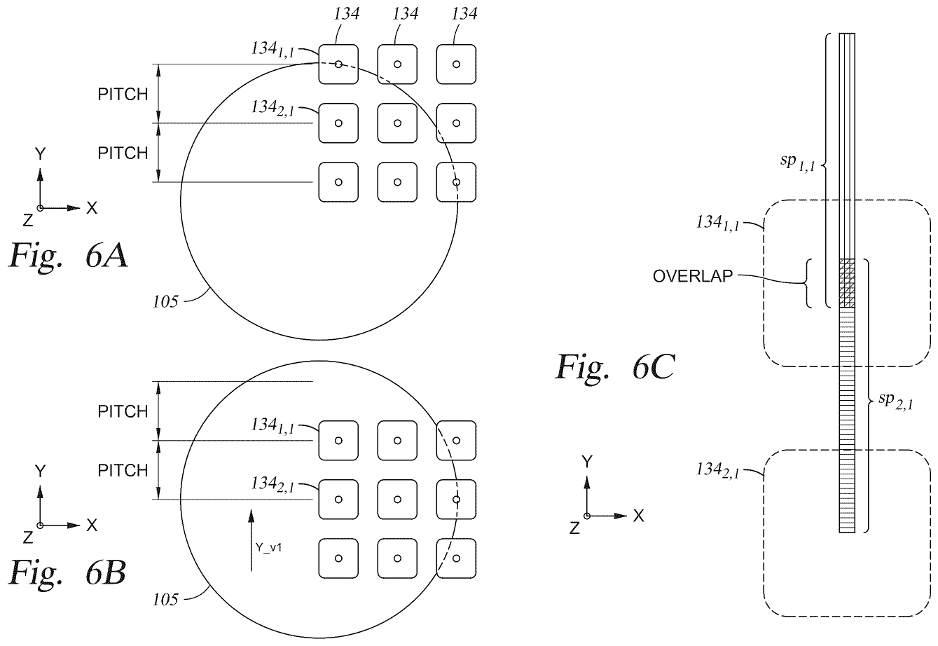

In a processing tool 100 that includes a first electron beam device 134 and a second electron beam device 134 adjacent thereto in the y-axis, i.e., has an array of electron beam devices 134 with two or more rows, a scan pass of the first electron beam device 134 may overlap with a scan pass of the second electron beam device 134, as described below in connection with FIGS. 6A-C.

FIGS. 6A-B are plan views of an arrangement of an array of nine electron beam devices 134 relative to a substrate 105, and FIG. 6C is a schematic view of overlapping scan passes, according to one embodiment. In FIGS. 6A-B, an electron beam device 134_{1,1} is in a first row and first column of the array, and an electron beam device 134_{2,1} is in a second row and the first column of the array. In FIG. 6B, the stage 136 has moved the substrate 105 in the y-direction by more than one pitch, relative to FIG. 6A.

FIG. 6C illustrates overlapping scan passes for the electron beam device 134_{1,1} and the electron beam device 134_{2,1}. Note that the scan dimension in the y-axis direction is FIG. 6 is not drawn to the same scale as in FIGS. 6A-B, and the width of the scan passes in FIG. 6C are exaggerated, for the sake of illustrating overlap. The FOV of the electron beam device 134_{1,1} has traversed scan pass sp_{1,1}. The FOV of the electron beam device 134_{2,1} has traveled scan pass_{2,1}. An overlap region exists where a portion of the substrate 105 that was traversed by the FOV of the electron beam device 134_{2,1} has also been traversed by the FOV of the electron beam device 134_{1,1} because the stage 136 has moved the substrate 105 in the y-axis direction by more than the y-axis pitch of the electron beam device 134_{1,1} and the electron beam device 134_{2,1}.

One embodiment of a method of processing the substrate 105 includes disposing the substrate 105 on the stage 136 of the processing tool 100 having a plurality the electron beam devices 134, which are independently powered and independently controlled, concurrently and continuously directing a plurality of electron beams from the plurality of electron beam devices 134 to the substrate 105 to process (or write to, or expose) different areas of the substrate 105 concurrently, and moving each electron beam of the plurality of electron beams at a first speed in a first area of the substrate 105 and a second speed in a second area of the substrate 105, wherein the first speed is selected to deliver an exposure dose to the first area and the second speed is selected to deliver a non-exposure dose to the second area. The moving of each electron beam refers to moving each electron beam within the FOV of the corresponding electron beam device 134. In an example in which the substrate 105 includes a feature such as an electron-sensitive resist layer, the exposure dose is a dose that forms a pattern in the resist layer and the non-exposure dose is a dose below a pattern-forming exposure threshold of the resist layer. That is, for a positive tone resist, regions of the resist layer to which a non-exposure dose is delivered would not be removed when the resist layer is developed; for a negative tone resist, regions of the resist layer to which a non-exposure dose is delivered would be removed when the resist layer is developed. Delivering electrons to the substrate 105 while moving the electron beam at a speed within the FOV that delivers a non-exposure dose of electrons is advantageous for maintaining continuous electron emission while at the same time selectively writing to the substrate 105. Maintaining continuous electron emission of all of the electron beam devices 134 in the processing tool 100 can help stabilize beam characteristics, make beam characteristics more uniform among the electron beam devices 134, and provide a higher level of control over patterns written in the substrate 105.

In one example, moving the electron beam at a speed that delivers a non-exposure dose includes continuously emitting electrons but moving the electron beam sufficiently rapidly within the FOV such that the residence time is sufficiently low (e.g., the electrons are spread out over sufficient area) that the resist within the FOV is not exposed, i.e., is not transformed to be removed in development of a positive tone resist and not transformed to remain in development of a negative tone resist. This may be combined with one or more other approaches for reducing electron flux density while continuously emitting electrons, such as defocusing the electron beam, and/or with other approaches such as beam blanking. Thus, although electrons are continuously emitted to the substrate, a non-exposure dose can be achieved by controlling the residence time (e.g., through rapid motion of the electron beam in the FOV) and/or controlling the flux density of the electron beam.

Another method includes rapidly moving the electron beam from a first pattern within the FOV of an electron beam device 134 to a second pattern within the FOV of the electron beam device 134, the rapid movement of the electron beam traversing a resist region (within the FOV) between the first pattern and the second pattern while delivering electrons to the resist region between the first pattern and the second pattern, but delivering the electrons with a sufficiently low electron flux density that a non-exposure dose is delivered and the resist region between the first pattern and the second pattern is not exposed.

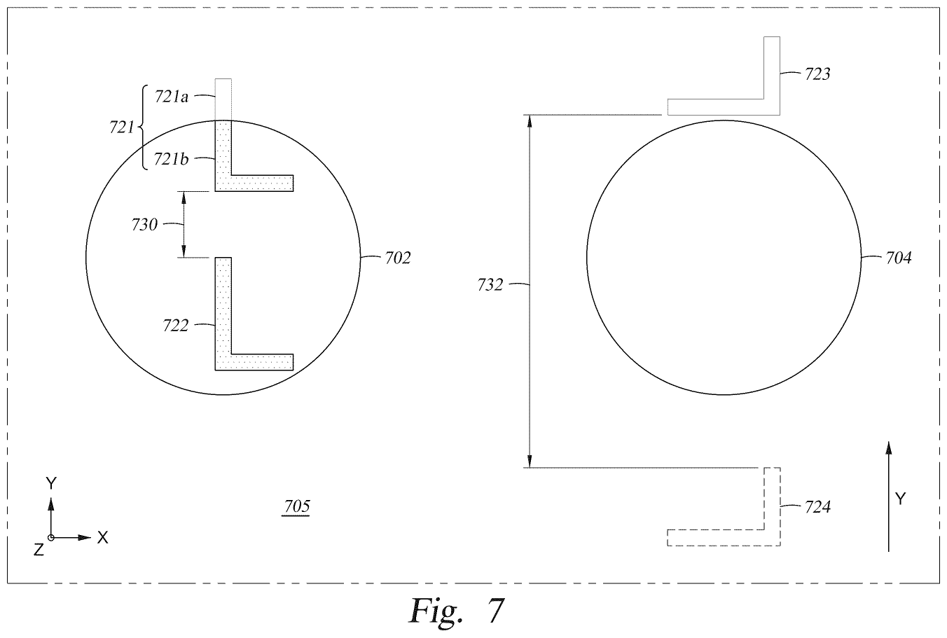

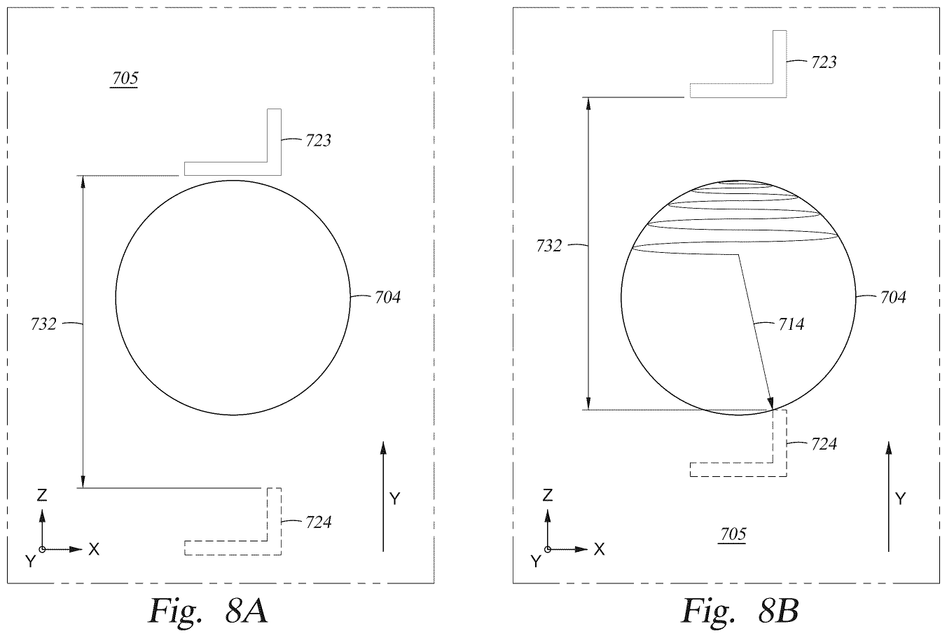

Aspects of the above methods of delivering a non-exposure dose will now be described in connection with FIGS. 7 and 8A-8B.

FIG. 7 is a plan view of a region 705 of a substrate 105 and corresponding fields of view (FOVs) of two adjacent features to be exposed. In FIG. 7, a first FOV 702 and a second FOV 704 are shown side by side, e.g., as may correspond to two side by side electron beam devices 134 in a row of an array. However, the electron beam devices 134 and their corresponding FOVs may be non-adjacent in the row or in the array, e.g., in first and third columns of the three-column array of FIGS. 4A-4B, 5A-5C, and 6A-6B. In FIG. 7, the FOVs are circular regions but the FOVs can be elliptical regions, rectangular regions, square regions, or the like.

In FIG. 7, first to fourth patterns 721, 722, 723, and 724 are shown. The first to fourth patterns 721, 722, 723, and 724 are patterns written to the substrate 105 according to a plan or recipe for writing patterns on the substrate 105. The substrate 105 is moving in the fast-axis direction (y-direction) as indicated by the upward pointing arrow. The first pattern 721 includes a first pattern portion 721a that has been written to the substrate and has moved out of the first FOV 702 due to motion in the y-direction of the substrate 105 relative to the first FOV 702. The first pattern 721 also includes a second pattern portion 721b, contiguous with the first pattern portion 721a, that is still within the first FOV 702. The second pattern 722 is entirely within the first FOV 702. The third pattern 723 is outside the second FOV 704. The third pattern 723 was written to the substrate 105 while the corresponding area of the substrate 105 traversed the second FOV 704. The fourth pattern 724 is a pattern that will be written as the corresponding area of the substrate 105 traverses the second FOV 704. The fourth pattern 724 is drawn in dashed lines because the fourth pattern 724 is a pattern that has not yet been written because the corresponding area of the substate 105 has not yet entered the second FOV 704. Each of the first, second, third, and fourth patterns 721, 722, 723, and 724 are exposure areas of the substrate 105 in the region 705 where transformation of substrate material is intended by processing using the electron beam devices. Other areas of the substrate 105 in the region 705 are non-exposure areas of the substrate, where no transformation of substrate material is intended.

In one embodiment, all of the electron beam devices 134 are powered on continuously as the substrate 105 is processed. That is, electrons are continuously directed to the areas of the substrate 105 within the first and second FOVs 702, 704. As described above, maintaining continuous electron emission of all of the electron beam devices 134 in the processing tool 100 can help stabilize beam characteristics, make beam characteristics more uniform among the electron beam devices 134, and provide a higher level of control over patterns written in the substrate 105. However, in such a case of processing the substrate 105 using multiple electron beam devices 134 that concurrently and continuously emit electrons, a circumstance may arise in which a plan or recipe for writing patterns on the substrate 105 calls for a pattern to be written in one area, an exposure area, of the substrate 105 by a first one of the electron beam devices 134 (e.g., in the first FOV 702) but, in another area of the substrate 105, a non-exposure area, a second one of the electron beam devices 134 is not to write a pattern (e.g., in the second FOV 704). In this circumstance, due to the continuous electron emission of the second electron beam device, provisions should be made to avoid exposing the substrate in the non-exposure area. Thus, using FIG. 7 as an example, with the substrate 105 moving at a constant velocity in the fast-axis direction (upwards along the y-direction in FIG. 7), the first FOV 702 of a first electron beam device 134 is traversing an area of the substrate 105 to which one or more patterns are to be written in exposure areas, and to which an exposure dose is to be delivered in those areas (i.e., delivered to write the first and second patterns 721, 722). However, the second FOV 704 of a second electron beam device 134 is traversing an area of the substrate 105 that is a non-exposure area, in which no pattern is to be written.

In the first FOV 702, the first and second patterns 721, 722 are close enough in the y-direction (i.e., a distance 730 is small enough) that the area of the substrate 105 corresponding to the second pattern 722 has moved (in the y-direction) into the first FOV 702 before the area of the substrate 105 corresponding to the first pattern 721 has moved out of the first FOV 702. Accordingly, in one embodiment of a method of processing the substrate 105, when the electron beam in the first FOV 702 has completed writing the first pattern 721, it is immediately moved or redirected within the first FOV 702 to commence writing the second pattern 722. The electron beam in the first FOV 702 is moved across the non-exposure area between the first pattern 721 and the second pattern 722 at a rate that delivers a non-exposure dose to the non-exposure area. For example, one method that continuously directs electrons onto the area of the substrate 105 in the first FOV 702 includes moving the electron beam at a speed sufficiently fast to avoid delivering an exposure dose as the electron beam travels the distance 730, which is the minimum dimension of the non-exposure area between the first pattern 721 and the second pattern 722.

The situation in the second FOV 704 is different from the first FOV 702. In the second FOV 704, the third and fourth patterns 723, 724 are too far apart in the y-direction (i.e., a distance 732 is too great and a non-exposure area too large) for their corresponding areas of the substrate 105 to be within the second FOV 704 at the same time. Accordingly, when the electron beam in the second FOV 704 has completed writing the third pattern 723, it cannot be immediately moved or redirected within the second FOV 704 to commence writing the fourth pattern 724.

An example method of addressing the above-described circumstance will now be described with reference to FIGS. 8A-8B. The method includes moving the electron beam in the second FOV 704 at a speed that is selected to deliver a non-exposure dose to the area of the substrate 105 within the second FOV 704. The method described in reference to FIGS. 8A and 8B can be used in the situation depicted in FIG. 7.

FIGS. 8A-8B are plan views of a region of a substrate and a corresponding field of view of a feature to be exposed. FIGS. 8A-8B show regions that correspond to the second FOV 704 of FIG. 7. FIG. 8A represents passage of the substrate 105 across the second FOV 704 at a point earlier in time than FIG. 8B.

In FIG. 8A, the third pattern 723 has been written by the electron beam as the corresponding area of the substrate 105 traversed the second FOV 704 in the y-axis direction. The third pattern 723 has exited the second FOV 704. The electron beam continues to deliver electrons to non-exposure areas of the substrate 105 within the second FOV 704 even though no pattern is to be written, i.e., even though the area of the substrate 105 corresponding to the fourth pattern 724 has not yet entered the second FOV. Accordingly, referring to FIG. 8B, the electron beam is moved along a continuous path 714 (continuous because the electron beam is continually delivering electrons to the substrate 105) at a speed that is sufficiently fast that the area traced by the path 714 in a non-exposure area of the substrate receives a non-exposure dose of electrons. In FIG. 8B, the path 714 is shown as a side-to-side ‘S’-like path or snaking or serpentine path, but various other non-linear paths can be used such as zig-zags, swirls, boustrophedon, or the like. The speed of the movement of the electron beam is controlled to be sufficiently high, i.e., the electron beam is moved fast enough, that the electron flux density remains below the exposure threshold of the layer being dosed (or irradiated) to deliver a non-exposure dose to the non-exposure area of the substrate. In FIG. 8B, the path 714 does not cross itself but other paths can be used that do cross, with the speed of the movement of the electron beam being controlled to ensure that the crossing points, which are dosed more than once due to the crossing paths, nonetheless receive a sufficiently low dose that exposure does not occur at the crossing points.

In FIG. 8B, the substrate 105 has moved in the y-axis direction (relative to FIG. 8A) sufficiently that the area of the substrate 105 corresponding to the fourth pattern 724 has begun to enter the second FOV 704. The substrate 105 has traversed the second FOV 704 by the distance 732 of the non-exposure area between patterns, during which time the electron beam was moved at a speed selected to deliver a non-exposure dose to the non-exposure area. Once at least part of the fourth pattern 724 enters the second FOV 704, the electron beam is immediately moved or redirected within the second FOV 704 to the area of the substrate 105 where the fourth pattern 724, an exposure area of the substrate, has entered the second FOV 704, and the electron beam is controlled to resume writing, i.e., exposing the substrate, which may include returning the motion of the electron beam to the first speed (e.g., as was used to write the third pattern 723) to deliver an exposure dose to the exposure area of the fourth pattern 724.

As described above, one or more embodiments provide high throughput processing of a substrate using concurrent writing by a plurality of electron beam devices. The electron beam devices are independently powered and independently controlled, enabling fast processing of a substrate by performing concurrent processing of sections of the substrate with independently operated electron beam devices.

While the foregoing is directed to embodiments of the present invention, other and further embodiments of the present disclosure may be devised without departing from the basic scope thereof, and the scope thereof is determined by the claims that follow.

We claim:

1. A method, comprising:
disposing a substrate on a stage of a processing tool comprising a plurality of independently powered, independently controlled modular electron beam devices;
concurrently directing a plurality of electron beams from the plurality of electron beam devices to the substrate to process different areas of the substrate concurrently; and
while directing the electron beams to the substrate, moving the substrate at a first constant velocity during a first scan pass and at a second constant velocity during a second scan pass, the first constant velocity being different from the second constant velocity.

2. The method of claim 1, wherein the first constant velocity is determined based on a first density of exposure during the first scan pass and the second constant velocity is determined based on a second density of exposure during the second scan pass.

3. The method of claim 2, wherein the first constant velocity is based on a first maximum density of exposure of a first area of the substrate during the first scan pass and the second constant velocity is based on a second maximum density of exposure of a second area of the substrate during the second scan pass.

4. A method, comprising:
disposing a substrate on a stage of a processing tool comprising a plurality of independently powered, independently controlled electron beam devices;
selecting a power for each electron beam device based on a plan for writing features on the substrate; and
concurrently directing a plurality of electron beams from the plurality of electron beam devices, at each respective selected power, to the substrate to process different areas of the substrate concurrently.

5. The method of claim 4, wherein each selected power is based on a planned exposure rate of the substrate within an area of the substrate to be processed using the respective electron beam device.

6. The method of claim 5, wherein the planned exposure rate is based on a material forming a layer of the substrate, a thickness of the layer of the substrate, or both.

7. The method of claim 6, wherein the power is selected from a data table.

8. The method of claim 7, wherein the power is automatically selected by a digital control system.

9. A method, comprising:
disposing a substrate on a stage of a processing tool comprising a plurality of independently powered, independently controlled electron beam devices;
concurrently and continuously directing a plurality of electron beams from the plurality of electron beam devices to the substrate to process different areas of the substrate concurrently; and
moving each electron beam of the plurality of electron beams at a first speed in a first area of the substrate and a second speed in a second area of the substrate, wherein the first speed is selected to deliver an exposure dose to the first area and the second speed is selected to deliver a non-exposure dose to the second area.

10. The method of claim 9, further comprising, while concurrently and continuously directing the plurality of electron beams from the plurality of electron beam devices to the substrate, moving the substrate at a constant velocity.

11. The method of claim 10, wherein moving the substrate at a constant velocity comprises moving the substrate at a first constant velocity during a first scan pass of the substrate and moving the substrate at a second constant velocity, different from the first constant velocity, during a second scan pass of the substrate.

12. The method of claim 11, wherein the first constant velocity is determined based on a first density of exposure during the first scan pass and the second constant velocity is determined based on a second density of exposure during the second scan pass.

13. The method of claim 9, wherein moving the electron beam at the second speed in the second area of the substrate comprises moving the electron beam from a first exposure area of the substrate, across a non-exposure area of the substrate, to a second exposure area of the substrate.

14. The method of claim 13, wherein moving the electron beam at the second speed in the second area of the substrate comprises selecting a path that minimizes a distance, within the non-exposure area, that is illuminated by the electron beam.

15. The method of claim 14, further comprising defocusing the electron beam while the electron beam illuminates the second area of the substrate.

16. The method of claim 9, wherein the moving the electron beam at the second speed in the second area includes blanking or defocusing the electron beam.

17. The method of claim 9, wherein each electron beam device is a modular electron beam device that has analog controls, a digital controller, and a D-A converter that couples the digital controller to the analog controls.

18. The method of claim 9, further comprising selecting a power for each electron beam device based on a plan for writing features on the substrate, wherein each selected power is based on a planned exposure rate within an area of the substrate to be processed using the respective electron beam device.

19. The method of claim 9, wherein the second speed is sufficiently fast that the electron flux density delivered to the second area of the substrate remains below an exposure threshold of the substrate to deliver a non-exposure dose to the second area of the substrate.

20. The method of claim 9, wherein moving each electron beam of the plurality of electron beams at the second speed in a second area of the substrate comprises moving at least a portion of the electron beams in a non-linear manner.
